(19) United States
(12) Patent Application Publication
(10) Pub. No.: US 2025/0209359 A1
(43) Pub. Date: Jun. 26, 2025

(54) SIGNAL TRANSMISSION DEVICE AND QUANTUM COMPUTER SYSTEM FOR QUANTUM BIT

(71) Applicant: Industrial Technology Research Institute, Hsinchu (TW)

(72) Inventors: Che-Hao Li, Tainan City (TW); Po-Sheng Chang, Kaohsiung City (TW); Po-Yuan Hsu, Taipei City (TW); Chien-Nan Kuo, Hsinchu City (TW)

(73) Assignee: Industrial Technology Research Institute, Hsinchu (TW)

(21) Appl. No.: 18/613,052

(22) Filed: Mar. 21, 2024

(30) Foreign Application Priority Data
Dec. 26, 2023 (TW) 112150824

(51) Int. Cl. G06N 10/40; H05K 7/20

(52) U.S. Cl. CPC G06N 10/40; H05K 7/20409

(57) ABSTRACT

Disclosed are a signal transmission device and a quantum computer system for a qubit. The signal transmission device includes a transceiver circuit, a first sensing circuit board, a thermal insulation shell and a second sensing circuit board. The first sensing circuit board is coupled to the transceiver circuit. The thermal insulation shell separates a thermal insulation area. The second sensing circuit board is coupled to the qubit. The second sensing circuit board and the qubit are located in the thermal insulation area of the thermal insulation shell. The transceiver circuit is located outside the thermal insulation area of the thermal insulation shell. The first sensing circuit board and the second sensing circuit board perform mutual induction to produce energy changes, and the transceiver circuit transmits and receives a signal with the qubit through the mutual induction between the first sensing circuit board and the second sensing circuit board.

### CROSS-REFERENCE TO RELATED APPLICATION

This application claims the priority benefit of Taiwan application serial no. 112150824, filed on Dec. 26, 2023. The entirety of the above-mentioned patent application is hereby incorporated by reference herein and made a part of this specification.

### TECHNICAL FIELD

The present disclosure relates to a technology for quantum computing and controlling signal transmission, and in particular to a signal transmission device and a quantum computer system for a quantum bit.

### BACKGROUND

A quantum computer is a device having technologies corresponding to the use of quantum bits (qubits) and quantum logic for general-purpose computing. The concept of a quantum computer involves controlling quantum states and recording and computing information by measuring the quantum states. Different than a conventional computer, which can only record one kind of information of bits at a time, a quantum bit is able to present two types of bit status, which are “0” and “1”, at the same time. In theory, quantum computers compute faster than the current computer devices.

All currently known qubit technologies need to be performed in cryogenic environments to function properly, and usually, equipment used to control qubits only operates at room temperature. Therefore, control signals need to be transmitted from a room temperature environment to the qubits in a cryogenic environment via transmission lines through the barrier of a temperature controlling device. However, these transmission lines not only carry signals, but also conduct thermal energy. The way the transmission lines transmit signals also consumes power and generates heat, which leads to reduction of the effectiveness of thermal insulation and an increase in the error rate of signals in qubits. The interference caused by the lines to read signals may also result in a decrease in signal quality. Therefore, how to reduce the thermal energy that is transferred into the cryogenic environment along with the transmitted signals during signal transmission is one of the current research directions in qubit and quantum computer technologies.

### SUMMARY

The disclosure provides a control signal transmission device for quantum computing, which utilizes near-field coupling to exchange signals with a quantum bit (qubit), thereby reducing the number of thermal conduction paths.

According to the embodiments of the disclosure, a signal transmission device includes a transceiver circuit, a first sensing circuit board, a thermal insulation shell and a second sensing circuit board. The first sensing circuit board is coupled to the transceiver circuit. The thermal insulation shell is used to separate a thermal insulation area. The second sensing circuit board is coupled to the qubit. The second sensing circuit board and the qubit are located in the thermal insulation area of the thermal insulation shell. The transceiver circuit is located outside the thermal insulation area of the thermal insulation shell. The first sensing circuit board and the second sensing circuit board perform mutual induction to produce energy changes, and the transceiver circuit transmits and receives a signal with the qubit through the mutual induction between the first sensing circuit board and the second sensing circuit board.

According to the embodiments of the disclosure, a quantum computer system includes a computer, a signal transmission device and a qubit. The computer transmits and receives a signal with the qubit through the signal transmission device. The signal transmission device includes a transceiver circuit, a first sensing circuit board, a thermal insulation shell, and a second sensing circuit board. The first sensing circuit board is coupled to the transceiver circuit. The thermal insulation shell is used to separate a thermal insulation area. The second sensing circuit board is coupled to the qubit. The second sensing circuit board and the qubit are located in the thermal insulation area of the thermal insulation shell, while the transceiver circuit is located outside the thermal insulation area of the thermal insulation shell. The first sensing circuit board and the second sensing circuit board perform mutual induction to produce energy changes, and the transceiver circuit transmits and receives the signal with the qubit through the mutual induction between the first sensing circuit board and the second sensing circuit board.

Based on the above, according to the embodiments of the disclosure, a signal transmission device used for a qubit and a quantum computer system utilize mutual induction between two sensing circuit boards as a method of near-field coupling to transmit and receive a signal with the qubit without directly connecting a transmission line or other thermal conduction paths to the cryogenic environment where the qubit is located. As a result, the embodiments reduce the number of heat conduction paths, thereby lowering the possibility of disrupting the cryogenic environment and maintaining the operational quality of the qubit. In other words, the embodiments avoid a direct corporeal connection between the cryogenic environment where the qubit is located and the external room-temperature environment, further reducing the conduction of thermal energy effectively by insulating thermal sources with space.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a schematic diagram of a signal transmission device 100 for a qubit in accordance with a first embodiment of the disclosure.

FIG. 2 illustrates a schematic diagram of a quantum computer system 200, relating to a second embodiment of the disclosure.

FIG. 3 illustrates a schematic diagram of a signal transmission device for a qubit according to a third embodiment of the disclosure.

FIG. 4 illustrates a schematic diagram of a circuit structure that includes a transceiver circuit, a first sensing circuit board, and a second sensing circuit board in a signal transmission device according to each embodiment of the disclosure.

FIG. 5 is a structure diagram of a tuning circuit in a transceiver circuit in accordance with the embodiments of the disclosure.

FIG. 6 illustrates a simulation diagram for transmitting and receiving signals based on the circuit structure shown in FIG. 5.

FIG. 7 illustrates a structure diagram presenting a physical cross section of a signal transmission device 700 in line with a fourth embodiment of the disclosure. FIG. 8 is another physical structure diagram of the signal transmission device 700 in the fourth embodiment of the disclosure.

FIG. 9 illustrates a schematic diagram of a signal transmission device for a qubit, conforming to the fifth embodiment of this disclosure.

FIG. 10 illustrates a schematic diagram of a signal transmission device 1000 for a qubit, conforming to the sixth embodiment of the disclosure.

FIG. 11 illustrates a flowchart of a signal transmission method for a qubit, conforming to each embodiment of the disclosure.

### DETAILED DESCRIPTION OF DISCLOSED EMBODIMENTS

To maintain a cryogenic environment where a quantum bit (qubit) is located and to prevent the insulation of the environment from being compromised, the disclosure employs two sensing circuit boards (such as sensing coils or similar circuit structures) that transmit and receive signals with the qubit located in the cryogenic environment through near-field communication or near-field coupling. This approach avoids direct contact between the qubit and the external environment via transmission lines. In other words, the embodiments of the disclosure utilize near-field communication or near-field coupling to minimize thermal conduction. Moreover, in comparison with far-field wireless transmission, the embodiments of the disclosure also result in less interference between each qubit. Furthermore, the sensing circuit board may be arranged on an inner layer of a thermal insulation shell to save more space for the arrangement of a signal transmission device. A plurality of signal transmission devices, quantum computer systems, and circuit architectures of the quantum computer systems applicable to quantum computers are proposed as embodiments of the disclosure. A user of the embodiments may, according to the user's requirements, adopt other realization methods that are derived from the embodiments described hereinafter and conform to the disclosure.

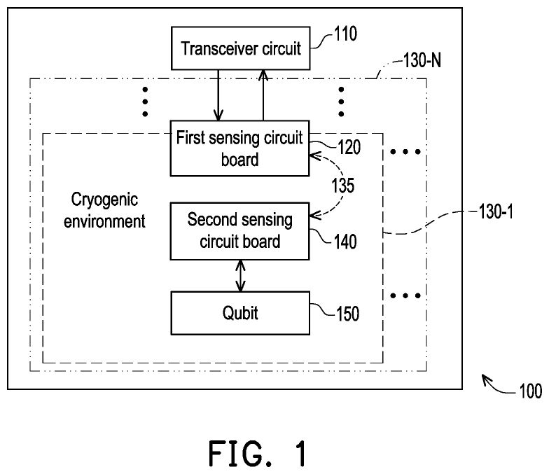

FIG. 1 illustrates a schematic diagram of a signal transmission device 100 for a qubit in accordance with a first embodiment of the disclosure. The signal transmission device 100 is part of a quantum computer system. The signal transmission device 100 for a qubit 150 includes a transceiver circuit 110, a first sensing circuit board 120, at least a thermal insulation shell layer (thermal insulation shell layers 130-1 to 130-N are used as examples in this embodiment), and a second sensing circuit board 140. The first sensing circuit board 120 is coupled to the transceiver circuit 110. The second sensing circuit board 140 is coupled to the qubit 150.

Thermal insulation shell layers 130-1 to 130-N are used to separate a thermal insulation area. Since the qubit 150 operates in the cryogenic environment, the quantum computer system and signal transmission device 100 in this embodiment utilize the multiple thermal insulation shell layers 130-1 to 130-N to incrementally achieve thermal insulation and maintain specific temperatures. The thermal insulation shell has a structure similar to a multi-layer refrigerator or Dewar flask, using a multi-layer vacuum structure to maintain low temperatures internally. A predicted temperature value in the thermal insulation area in this embodiment may be 1K (−272.15° C.). However, the temperature in the aforementioned thermal insulation area is significantly lower than 1K (−272.15° C.). A user of this embodiment may set and adjust the preset temperature value in accordance with the current technology used for setting the temperature of a qubit. The preset temperature value is not limited to the aforementioned example. The material for the thermal insulation shell layers 130-1 to 130-N may be ceramic.

In this embodiment, the second sensing circuit board 140 and the qubit 150 are located in the thermal insulation area of the thermal insulation shell layers 130-1 to 130-N. The transceiver circuit 110 is located outside the thermal insulation area of the thermal insulation shell layers 130-1 to 130-N. As shown in FIG. 1, the first sensing circuit board 120 is arranged on the thermal insulation shell layer 130-1 (e.g., on the inside of the thermal insulation shell layer 130-1). In another embodiment that conforms to the disclosure, a first sensing circuit board 120 of FIG. 1 may be arranged in a thermal insulation area of thermal insulation shell layers 130-1 to 130-N.

The first sensing circuit board 120 and the second sensing circuit board 140 induce each other to produce energy changes, as indicated by a dashed arrow 135. There is no direct contact between the first sensing circuit board 120 and the second sensing circuit board 140. There is also no medium (such as air or non-conductive insulation materials) between the first sensing circuit board 120 and the second sensing circuit board 140. The transceiver circuit 110 transmits and receives signals with the qubit 150 through the mutual induction between the first sensing circuit board 120 and the second sensing circuit board 140. Specifically, the transceiver circuit 110 utilizes near-field communication or near-field coupling to transmit and receive signals with the qubit 150 through the mutual induction between the first sensing circuit board 120 and the second sensing circuit board 140. When using technologies conforming to the embodiments of the disclosure, the first sensing circuit board 120 and the second sensing circuit board 140 can achieve “mutual induction” for signal transmission by means of a sensing coil, an antenna, capacitive coupling, or the like.

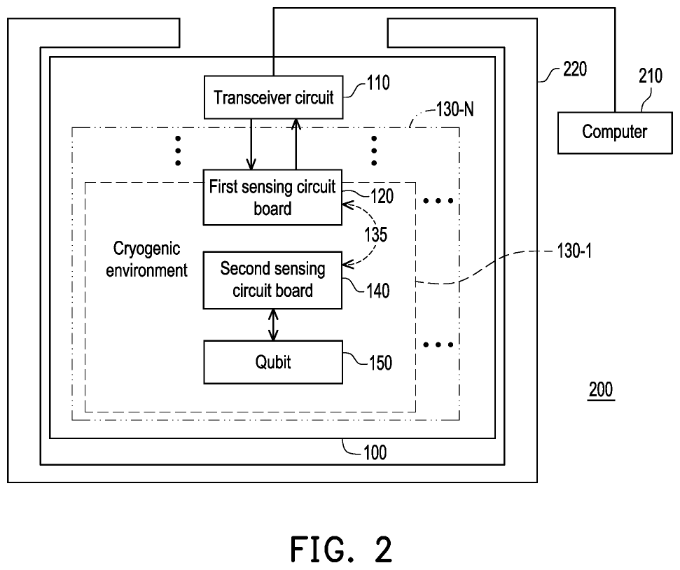

FIG. 2 illustrates a schematic diagram of a quantum computer system 200, relating to a second embodiment of the disclosure. The quantum computer system 200 in this embodiment not only includes all elements of a signal transmission device 100, which is shown in FIG. 1, but also includes a computer 210 and an insulator 220. The computer 210 transmits and receives signals with a qubit 150 through the signal transmission device 100. Specifically, the computer 210 provides read signals to a transceiver circuit 110, and transmits read input signals among the read signals to the qubit 150 through the transceiver circuit 110, a first sensing circuit board 120, and a second sensing circuit board 140. Read output signals from the qubit are also transmitted to the computer 210 through the transceiver circuit 110, the first sensing circuit board 120, and the second sensing circuit board 140. The insulator 220 is used to further isolate thermal energy and prevent thermal conduction.

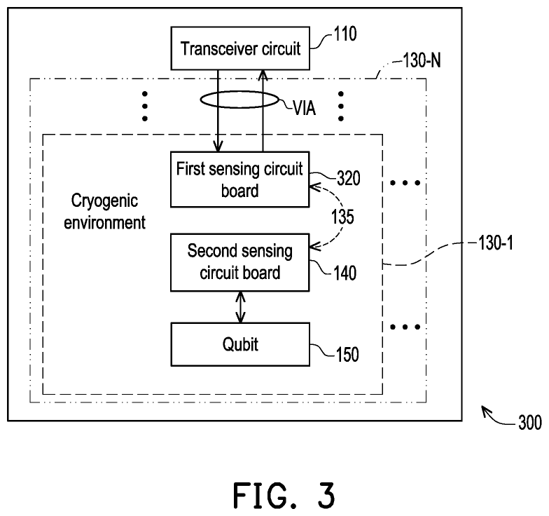

FIG. 3 illustrates a schematic diagram of a signal transmission device for a qubit according to a third embodiment of the disclosure. FIG. 3 is similar to FIG. 1, but the difference is that in FIG. 3, a first sensing circuit board 320 of the signal transmission device 300 is arranged in an insulated area of a thermal insulation shell layer 130-1, rather than on the thermal insulation shell layer 130-1. Specifically, the first sensing circuit board 320 may be arranged on the inside of the thermal insulation shell layer 130-1, or in a deeper area of the thermal insulation shell layer 130-1. A transceiver circuit 110 is arranged on the outside of a thermal insulation shell layer 130-N, or in an area further outward. The transceiver circuit 110 is coupled to the first sensing circuit board 320 through one or a plurality of via holes penetrating the thermal insulation shell layers 130-1 to 130-N for mutual signal transmission. In other embodiments conforming to the disclosure, the signal transmission between the transceiver circuit 110 and the first sensing circuit board 320 may also be realized through near-field coupling. For example, in FIG. 3, two additional sensing circuit boards are arranged between the transceiver circuit 110 and the first sensing circuit board 320 for signal transmission.

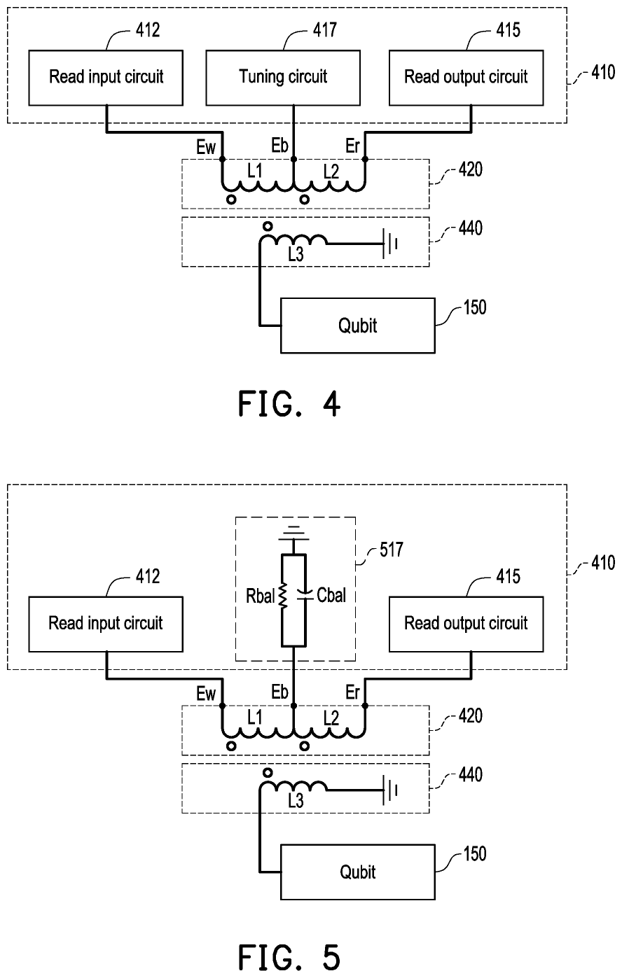

FIG. 4 illustrates a schematic diagram of a circuit structure that includes a transceiver circuit 410, a first sensing circuit board 420, and a second sensing circuit board 440 in a signal transmission device according to each embodiment of the disclosure. In this embodiment, the transceiver circuit 410 includes a read input circuit 412, a read output circuit 415, and a tuning circuit 417. The read input circuit 412 provides a read input signal from a computer to the first sensing circuit board 420. The read output circuit 415 receives a read output signal, which is generated based on the data in a qubit 150, from the first sensing circuit board 420.

In this embodiment, the first sensing circuit board 420 and the second sensing circuit board 440 utilize a transformer-based duplex structure to realize bidirectional transmission. As shown in FIG. 4, the first sensing circuit board 420 includes a read input terminal Ew, a balance terminal Eb, a read output terminal Er, a first inductor L1, and a second inductor L2. A first terminal of the first inductor L1 serves as the read input terminal Ew, and a second terminal of the first inductor L1 is coupled to the balance terminal Eb. A first terminal of the second inductor L2 is coupled to the balance terminal Eb, and a second terminal of the second inductor L2 is coupled to the read output terminal Er. The read input terminal Ew is coupled to the read input circuit 412. The balance terminal Eb is coupled to the tuning circuit 417, and the read output terminal Er is coupled to the read output circuit 415. The read input terminal Ew, the balance terminal Eb, and the read output terminal Er correspond to the aforementioned via holes on thermal insulation shell layers 130-1 to 130-N respectively. The read input circuit 412, the read output circuit 415, and the tuning circuit 417 are, through these via holes, electrically connected to the read input terminal Ew, the read output terminal Er, and the balance terminal Eb of the first inductor L1, respectively. The second sensing circuit board 440 includes a third inductor L3. A first terminal of the third inductor L3 is coupled to the qubit 150, and a second terminal of the third inductor L3 is coupled to a reference voltage terminal (e.g., a ground terminal).

The tuning circuit 417 is used to control and adjust the impedance of the first sensing circuit board 420, thereby adjusting the frequency of a read input signal or a read output signal. The tuning circuit 417 in this embodiment is an example from an electrical-balance duplexer. FIG. 5 is a structure diagram of a tuning circuit in a transceiver circuit 410 in accordance with the embodiments of the disclosure. In FIG. 5, a tuning circuit 517 includes a resistor Rbal and a capacitor Cbal. A first terminal of the resistor Rbal is coupled to a balance terminal Eb, and a second terminal of the resistor Rbal is coupled to a reference voltage terminal (a ground terminal). A first terminal of the capacitor Cbal is coupled to the balance terminal Eb, and a second terminal of the capacitor Cbal is coupled to the reference voltage terminal (the ground terminal). In an embodiment conforming to the disclosure, a resistor Rbal may be a fixed value resistor, and a capacitor Cbal may be a fixed value capacitor. The fixed value resistor and the fixed value capacitor form a fixed resistor-capacitor circuit with a broadband impedance design. In another embodiment conforming to the disclosure, a resistor Rbal may be a variable resistor, and a capacitor Cbal may be a variable capacitor. The aforementioned variable resistor and variable capacitor are controlled by a part of other control circuits in a transceiver circuit 410, enabling impedance modulation and making the variable resistor and the variable capacitor suitable for transmitting and receiving signals.

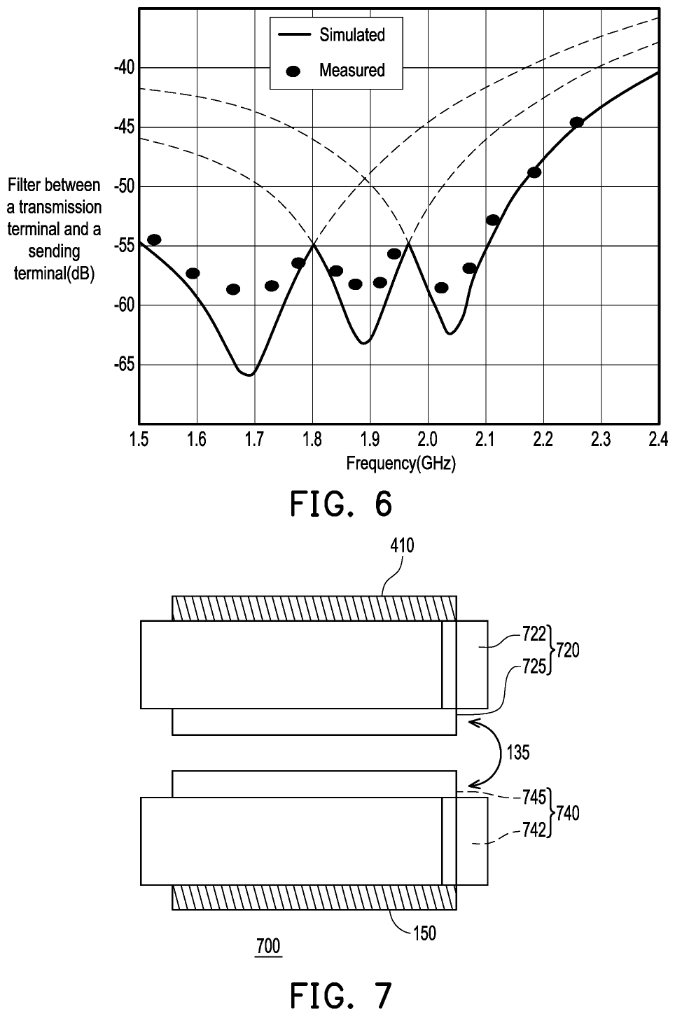

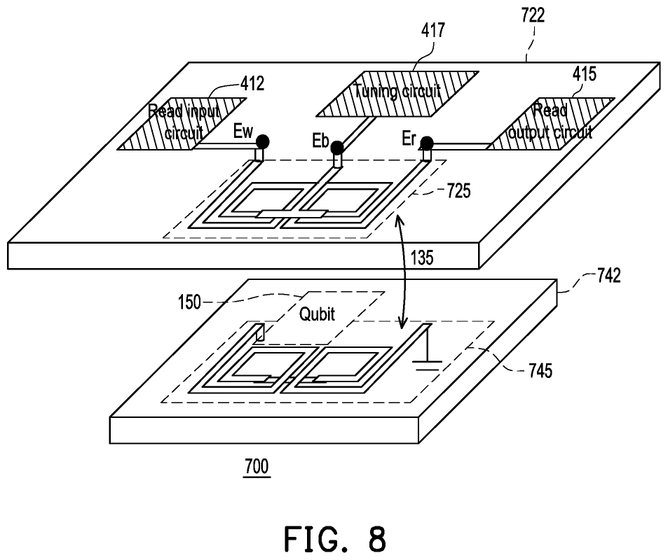

FIG. 6 illustrates a simulation diagram for transmitting and receiving signals based on the circuit structure shown in FIG. 5. In this embodiment of the disclosure, according to the aforementioned simulation diagram of the circuit structure, it is understood that when a tuning circuit 517 is a fixed resistor-capacitor circuit, frequencies around 1.7 GHz, 1.9 GHz, and 2.05 GHz enable signal transmission between a transceiver circuit and a qubit.

FIG. 7 illustrates a structure diagram presenting a physical cross section of a signal transmission device 700 in line with a fourth embodiment of the disclosure. FIG. 8 is another physical structure diagram of the signal transmission device 700 in the fourth embodiment of the disclosure. The fourth embodiment of the disclosure specifies a method for realizing a first sensing circuit board 720 and a second sensing circuit board 740 in detail. With reference to FIG. 7 and FIG. 8, the first sensing circuit board 720 in this embodiment includes a substrate 722 and a circuit 725. The substrate 722 may serve as an area that is part of the aforementioned thermal insulation shell layers (e.g., the thermal insulation shell layer 130-1 shown in FIG. 1). The circuit 725 of the first sensing circuit board 720 is arranged on the inside of a thermal insulation shell layer (the substrate 722). A transceiver circuit 410 (e.g., a read input circuit 412, a read output circuit 415, or a tuning circuit 417) is arranged on the outside of the thermal insulation shell layer (the substrate 722). The transceiver circuit 410 is coupled to the circuit 725 of the first sensing circuit board 720 through via holes on the thermal insulation shell layer (the substrate 722) (e.g., via holes corresponding to a read input terminal Ew, a balance terminal Eb, and a read output terminal Er respectively).

The second sensing circuit board 740 includes a substrate 742 and a circuit 745. A qubit 150 is arranged on one side of the substrate 742, while the circuit 745 is arranged on the other side of the substrate 742.

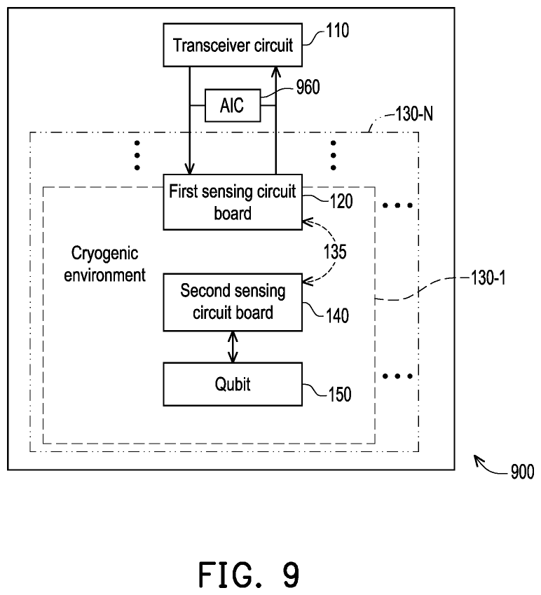

FIG. 9 illustrates a schematic diagram of a signal transmission device 900 for a qubit, conforming to the fifth embodiment of this disclosure. The difference between FIG. 9 and FIG. 1 is that in FIG. 9, the signal transmission device 900 additionally includes an analog interference cancellation circuit 960 (AIC 960) that is arranged between a transceiver circuit 110 and a first sensing circuit board 120. The AIC 960 reduces interference from a read input path (e.g., a read input circuit) with the characteristics of an analog circuit and corresponding elements. The AIC 960 is also applicable in other embodiments of the disclosure. For example, the AIC 960 may be used for the signal transmission device 300 in FIG. 3.

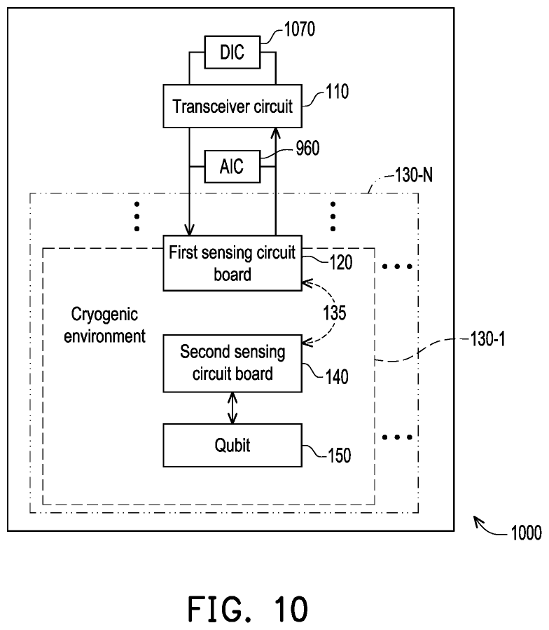

FIG. 10 illustrates a schematic diagram of a signal transmission device 1000 for a qubit, conforming to the sixth embodiment of the disclosure. The difference between FIG. 10 and FIG. 9 is that in FIG. 10, the signal transmission device 1000, in addition to an AIC 960, includes a digital interference cancellation circuit 1070 (DIC 1070) coupled to a transceiver circuit. The DIC 1070 reduces interference from a read input path using digital circuitry. The DIC 1070 is also applicable in other embodiments of the disclosure. For example, the DIC 1070 may be used for the signal transmission device 300 in FIG. 3.

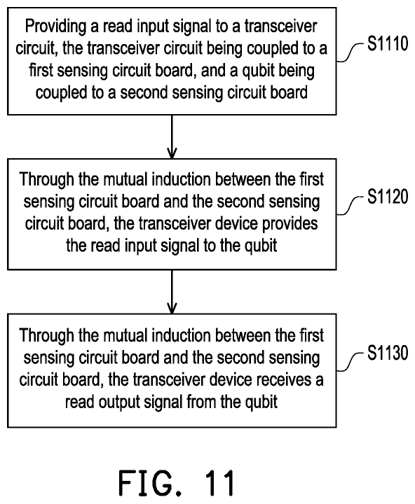

FIG. 11 illustrates a flowchart of a signal transmission method for a qubit, conforming to each embodiment of the disclosure. The signal transmission method in FIG. 11 is used in each signal transmission device of the disclosure. In FIG. 11, the signal transmission device 100 in FIG. 1 is used as an example. Please refer to both FIG. 1 and FIG. 11. When S1110 is performed, a computer provides a read input signal to a transceiver circuit 110. The transceiver circuit 110 is coupled to a first sensing circuit board 120, and a qubit 150 is coupled to a second sensing circuit board 140. When S1120 is implemented, through the mutual induction between the first sensing circuit board 120 and the second sensing circuit board 140, the transceiver device 110 provides the read input signal to the qubit 150. When S1130 is performed, through the mutual induction between the first sensing circuit board 120 and the second sensing circuit board 140, the transceiver device 110 receives a read output signal from the qubit 150. For corresponding implementations and detailed operations of the signal transmission method, please refer to the aforementioned embodiments.

In summary, the signal transmission device for a qubit and the quantum computer system described in the embodiment of the disclosure utilize the mutual induction between two sensing circuit boards as a method for near-field coupling to transmit signals to the qubit without connecting a directly-coupled thermal conduction path, such as a transmission line, to the cryogenic environment where the qubit is located. Therefore, the embodiment reduces the number of thermal conduction paths, which lowers the possibility of disrupting the cryogenic environment, thereby maintaining the operational quality of the qubit. In other words, the embodiment avoids direct and corporeal connections between the cryogenic environment where the qubit is located and the external environment at room temperature, thereby using space to insulate thermal sources and effectively reducing the conduction of thermal energy.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A signal transmission device for a quantum bit, comprising:
a transceiver circuit;
a first sensing circuit board coupled to the transceiver circuit;
a thermal insulation shell for separating a thermal insulation area; and
a second sensing circuit board coupled to the quantum bit,
wherein the second sensing circuit board and the quantum bit are located in the thermal insulation area of the thermal insulation shell, and the transceiver circuit is located outside the thermal insulation area of the thermal insulation shell,
the first sensing circuit board and the second sensing circuit board perform mutual induction to produce energy changes, and the transceiver circuit transmits and receives a signal with the quantum bit through the mutual induction between the first sensing circuit board and the second sensing circuit board.

2. The signal transmission device of claim 1, wherein the first sensing circuit board is disposed in the thermal insulation area of the thermal insulation shell.

3. The signal transmission device of claim 1, wherein the first sensing circuit board is disposed on the thermal insulation shell.

4. The signal transmission device of claim 1, wherein the transceiver circuit comprises:
a read input circuit providing a read input signal to the first sensing circuit board;
a read output circuit receiving a read output signal from the first sensing circuit board; and
a tuning circuit for controlling and adjusting an impedance of the first sensing circuit board to adjust a frequency of the read input signal or the read output signal.

5. The signal transmission device of claim 4, wherein the first sensing circuit board comprises:
a first inductor, wherein a first terminal of the first inductor serves as a read input terminal, and a second terminal of the first inductor is coupled to a balance terminal, the read input terminal being coupled to the read input circuit, and the balance terminal being coupled to the tuning circuit; and
a second inductor, wherein a first terminal of the second inductor is coupled to the balance terminal, and a second terminal of the second inductor is coupled to a read output terminal, the read output terminal being coupled to the read output circuit.

6. The signal transmission device of claim 5, wherein the read input terminal, the balance terminal, and the read output terminal correspond to a plurality of via holes on the thermal insulation shell, respectively.

7. The signal transmission device of claim 5, wherein the second sensing circuit board comprises a third inductor, a first terminal of the third inductor being coupled to the quantum bit, and a second terminal of the third inductor being coupled to a reference voltage terminal.

8. The signal transmission device of claim 4, wherein the tuning circuit is an electrical-balance duplexer.

9. The signal transmission device of claim 4, wherein the tuning circuit comprises:
a resistor, wherein a first terminal of the resistor is coupled to a balance terminal, and a second terminal of the resistor is coupled to a reference voltage terminal; and
a capacitor, wherein a first terminal of the capacitor is coupled to the balance terminal, and a second terminal of the capacitor is coupled to the reference voltage terminal.

10. The signal transmission device of claim 9, wherein the resistor is a variable resistor, and the capacitor is a variable capacitor.

11. The signal transmission device of claim 1, wherein the first sensing circuit board is disposed on an inner layer of the thermal insulation shell, and the transceiver circuit is disposed on an outer layer of the thermal insulation shell, the transceiver circuit being coupled to the first sensing circuit board through via holes penetrating the thermal insulation shell.

12. The signal transmission device of claim 1, wherein the transceiver circuit transmits and receives the signal with the quantum bit through near-field coupling through the mutual induction between the first sensing circuit board and the second sensing circuit board.

13. The signal transmission device of claim 1, wherein the first sensing circuit board and the second sensing circuit board each comprises a sensing coil.

14. The signal transmission device of claim 1, further comprising:
an analog interference cancellation circuit coupled between the transceiver circuit and the first sensing circuit board for reducing interference in a read input path.

15. The signal transmission device of claim 1, further comprising:
a digital interference cancellation circuit coupled to the transceiver circuit for reducing interference in a read input path.

16. A quantum computer system, comprising:
a computer;
a signal transmission device coupled to the computer; and
a quantum bit,
wherein the computer transmits and receives a signal with the quantum bit through the signal transmission device,
the signal transmission device comprising:
a transceiver circuit;
a first sensing circuit board coupled to the transceiver circuit;
a thermal insulation shell for separating a thermal insulation area; and
a second sensing circuit board coupled to the quantum bit,
wherein the second sensing circuit board and the quantum bit are located in the thermal insulation area of the thermal insulation shell, while the transceiver circuit is located outside the thermal insulation area of the thermal insulation shell,
wherein the first sensing circuit board and the second sensing circuit board perform mutual induction to produce energy changes, and the transceiver circuit transmits and receives the signal with the quantum bit through the mutual induction between the first sensing circuit board and the second sensing circuit board.

17. The quantum computer system of claim 16, wherein the first sensing circuit board is disposed in the thermal insulation area of the thermal insulation shell.

18. The quantum computer system of claim 16, wherein the transceiver circuit comprises:
a read input circuit providing a read input signal to the first sensing circuit board;
a read output circuit receiving a read output signal from the first sensing circuit board; and
a tuning circuit for controlling and adjusting an impedance of the first sensing circuit board to adjust a frequency of the read input signal or the read output signal.

19. The quantum computer system of claim 18, wherein the tuning circuit comprises:
a resistor, wherein a first terminal of the resistor is coupled to a balance terminal, and a second terminal of the resistor is coupled to a reference voltage terminal; and
a capacitor, wherein a first terminal of the capacitor is coupled to the balance terminal, and a second terminal of the capacitor is coupled to the reference voltage terminal.
